(19) United States
(12) Patent Application Publication
(10) Pub. No.: US 2014/0295674 A1
(43) Pub. Date: Oct. 2, 2014

(54) ANGLED GAS CLUSTER ION BEAM

(71) Applicant: INTERNATIONAL BUSINESS MACHINES CORPORATION, Armonk, NY (US)

(72) Inventors: Kangguo Cheng, Schenectady, NY (US); Ali Khakifirooz, Mountain View, CA (US); Richard S. Wise, Newburgh, NY (US)

(73) Assignee: International Business Machines Corporation, Armonk, NY (US)

(21) Appl. No.: 13/853,088

(22) Filed: Mar. 29, 2013

(51) Int. Cl. H01J 37/305; H01L 21/02; C23C 14/48; C23C 14/22; H01J 37/317

(52) U.S. Cl. CPC H01J 37/3053; C23C 14/221; H01J 37/3178; H01J 37/3171; C23C 14/48; H01L 21/02227
USPC 438/766; 204/298.36; 204/192.34; 118/723 R

(57) ABSTRACT

An angled gas cluster ion beam (“GCIB”) and methods for using the same are disclosed. Gas clusters are ionized to create a gas cluster beam directed towards a semiconductor wafer. The semiconductor wafer is positioned so that it intercepts the gas cluster beam at an angle that is non-perpendicular to the beam, so that the gas cluster ions in the beam react with structures on the semiconductor wafer asymmetrically, allowing for asymmetrical deposition on or etching of material thereon. According to one embodiment, GCIB is used to form asymmetric spacers having different materials, different thicknesses, or both.

### CROSS REFERENCE TO RELATED APPLICATION

This application is related to the following commonly-owned, co-pending U.S. patent application filed on even date herewith, the contents and disclosure of which is expressly incorporated by reference herein in its entirety: U.S. patent application Ser. No. ______ (FIS920120304US1), for “ASYMMETRIC SPACERS”.

### FIELD OF THE INVENTION

The present invention generally relates to semiconductor device fabrication, and particularly to semiconductor surface treatment processes and equipment using gas cluster ion beams.

### BACKGROUND

Complementary Metal-oxide-semiconductor (CMOS) technology is commonly used for fabricating field effect transistors (FETs) onto a semiconductor wafer. At the core of planar FETs, a channel region is formed in a n-doped or p-doped semiconductor substrate on which a gate structure is formed. The gates are serially connected to form discrete functional modules that together form advanced integrated circuits, such as CPUs, memory units, storage devices, and the like.

The processes employed to fabricate FETs are well known in the art, although there is a continuing trend towards ever smaller and more efficient devices, requiring making improvements to known techniques and devising new ones. In various steps of the fabrication process, it is necessary to deposit material onto the semiconductor wafer, to etch material already formed on the wafer, or otherwise treat the wafer surface. Together, these techniques sculpt the surface of the wafer to form functioning structures. Each technique has its own advantages and side effects that make it suitable for a particular step in the fabrication process, and plays a role in determining a manufacturer's cost structure.

A relatively new technique used in the fabrication process is a gas cluster ion beam (“GCIB”) system. GCIB allows for nano-scale modification of surfaces at a faster rate compared to some other known techniques, and without causing the substantial sub-surface damage that other techniques with comparable speed may cause. Generally, a GCIB system comprises a module that expands a high pressure gas into a vacuum. As the gas cools, it condenses into nano-sized crystalline clusters that are then emitted out of a nozzle. The clusters pass through differential pumping apertures into a high vacuum region where they are ionized through collisions with energetic electrons. The ionized clusters are accelerated and focused into a tight beam.

Referring now to FIG. 1, a gas cluster ion beam (“GCIB”) system 100 according to the prior art comprises a multi-part cluster formation module 10 (generically referred to herein as a first module), including a nozzle 14 emitting gas clusters. The GCIB system further comprises a beam formation module 20 (generically referred to herein as a second module) wherein the gas clusters from the gas cluster formation module 10 are ionized by using an ion source 24, and passed through to a beam modification module 30 (generically referred to herein as a third module) having a magnet 32 and a neutralizer 34, which accelerates the ionized gas clusters and neutralizes excess charge buildup within the device. The accelerated ion gas clusters are emitted and passed through a photovoltaic cell region 36. The resulting ionized gas cluster beam 50 collides at a substantially perpendicular angle with a substrate 44 resting on or attached to a mechanically scanned platen 42. In a typical application of the GCIB system, the substrate 44 is a silicon wafer. The substrate 44 and the platen 42 reside in a target module 40 (generically referred to herein as a fourth module). The first, second, third and fourth modules are positioned along a first horizontal axis 60.

GCIB is a very versatile technique because it can be used with virtually any gas, with varying intensity. Among other applications, it can be used for deposition, etching, and doping steps in the microelectronics fabrication process. These and other properties of the beam 50, such as beam size, the number of times it passes over an area of the substrate 44, and related factors depend on the particular application. In one typical micro fabrication process, the substrate 44 is a semiconductor wafer having, for example, a 300 mm diameter. The beam 50 spot size, i.e. the point where it is intercepted by the wafer, may be 1 cm in diameter. The wafer may be scanned approximately 100 times from left to right, using an approximately 3 mm step, beginning at a top side of the wafer. In typical GCIB applications, the platen 42 is movable along a vertical axis 70 and a second horizontal axis 80 (corresponding to the Y-axis and Z-axis).

Despite their advantages, current GCIB techniques are limited because they are applied to the target surface at a perpendicular angle, leading to substantially symmetric structures. For example, a GCIB system can be used to form spacer film layers onto a gate electrode and its flanking source and drain regions, and then again to etch the spacer film layers to form final spacer structures. However, without implementing hard-to-perfect, time consuming and costly masking steps, the final spacer structures are substantially identical both in their constituent material, thicknesses, and shapes.

While forming substantially identical structures is not necessarily disadvantageous, there are circumstances in which it would be desirable to form asymmetrical structures. For example, as transistors become smaller, the inherent parasitic capacitance of the gate-spacer-source/drain regions of a transistor have an increasing effect on the transistor's reliable operability. One way of decreasing the parasitic capacitance in these structures is to form the spacers asymmetrically on the source and drain sides of the gate electrode, by using different materials, different thicknesses, or both. The limitation in existing GCIB systems to facilitate this aim is due, in large part, to the fact that the beam emitting from a GCIB device collides with a semiconductor wafer at a right angle, resulting in nearly uniform changes to the wafer surface and creating symmetrical structures. Therefore, it would be desirable to develop a method and a system for using GCIB to manipulate a target surface asymmetrically.

### SUMMARY

According to one embodiment of the disclosed invention, an angled gas cluster ion beam system includes a first module for forming a collection of gas clusters, a second module for generating a gas cluster beam by using the collection of gas clusters formed by the first module, the second module communicating with the first module along a first axis extending through the modules; a third module for ionizing the gas cluster beam generated by the second module and for directing the gas cluster beam along the first axis, the third module communicating with the second module along the first axis; and a fourth module for housing a target surface, the fourth module configured to position the target surface at an acute angle from at least a second axis being substantially perpendicular to the first axis to intercept the gas cluster beam directed by the third module, the fourth module communicating with the third module along the first axis.

According to a further embodiment of the disclosed invention, a method for forming asymmetric structures using a angled gas cluster ion beam system includes the steps of forming a collection of gas clusters, using a first module; generating a gas cluster beam from the collection of gas clusters, using a second module; ionizing the gas cluster beam and directing the gas cluster beam along a first axis, using a third module; and intercepting the ionized gas cluster beam, using a fourth module, by positioning a target surface at an acute angle from a second axis being substantially perpendicular to the first axis.

### BRIEF DESCRIPTION OF THE DRAWINGS

FIG. 1 is a cross sectional side elevational view of a GCIB system directing a beam at a semiconductor wafer according to the prior art;

FIG. 2 is a cross sectional isometric view of a GCIB system directing a beam at a semiconductor wafer at an angle from a vertical axis, according to an embodiment of the disclosed invention;

FIG. 3A is a cross sectional front elevational view of a substrate layer formed during a step of a method for fabricating a FET device, according to an embodiment of the present invention;

FIG. 3B is a cross sectional front elevational view of a gate layer and a source/drain region formed onto the substrate layer depicted in FIG. 3A, according to an embodiment of the present invention;

FIG. 3C is a cross sectional front elevational view of a nitride spacer film layer formed onto the structure depicted in FIG. 3B using angled GCIB deposition, according to an embodiment of the present invention;

FIG. 3D is a cross sectional front elevational view of an oxide spacer film layer formed onto the structure depicted in FIG. 3C using angled GCIB deposition, according to an embodiment of the present invention;

FIG. 3E is a cross sectional front elevational view of an oxide spacer formed onto the structure depicted in FIG. 3D using angled GCIB etching, according to an embodiment of the present invention;

FIG. 3F is a cross sectional front elevational view of a nitride spacer formed onto the structure depicted in FIG. 3E using angled GCIB etching, having a relatively higher thickness than the oxide spacer depicted in FIG. 3E, according to an embodiment of the present invention;

FIG. 4A is a cross sectional front elevational view of an oxide spacer film layer formed onto the structure depicted in FIG. 3C using angled GCIB deposition, according to an embodiment of the present invention;

FIG. 4B is a cross sectional front elevational view of an oxide spacer formed onto the structure depicted in FIG. 4A using angled GCIB etching, according to an embodiment of the present invention;

FIG. 4C is a cross sectional front elevational view of a nitride spacer formed onto the structure depicted in FIG. 4B using angled GCIB etching, having a relatively equal thickness compared to the oxide spacer depicted in FIG. 4B, according to an embodiment of the present invention;

FIG. 5A is a cross sectional front elevational view of a spacer film layer formed onto the structure depicted in FIG. 3B, according to an embodiment of the present invention;

FIG. 5B is a cross sectional front elevational view of a spacer formed onto the structure depicted in FIG. 5A using angled GCIB etching, according to an embodiment of the present invention; and

FIG. 5C is a cross sectional front elevational view of a nitride spacer formed onto the structure depicted in FIG. 5B using angled GCIB etching, having an unequal thickness compared to the spacer depicted in FIG. 5B, according to an embodiment of the present invention.

### DETAILED DESCRIPTION

Embodiments will now be described herein with reference to the accompanying drawings, in which exemplary embodiments are shown. This disclosure may, however, be embodied in many different forms and should not be construed as limited to the exemplary embodiments set forth herein. Rather, these exemplary embodiments are provided so that this disclosure will be thorough and complete and will fully convey the scope of this disclosure to those skilled in the art. In the description, details of well-known features and techniques may be omitted to avoid unnecessarily obscuring the presented embodiments.

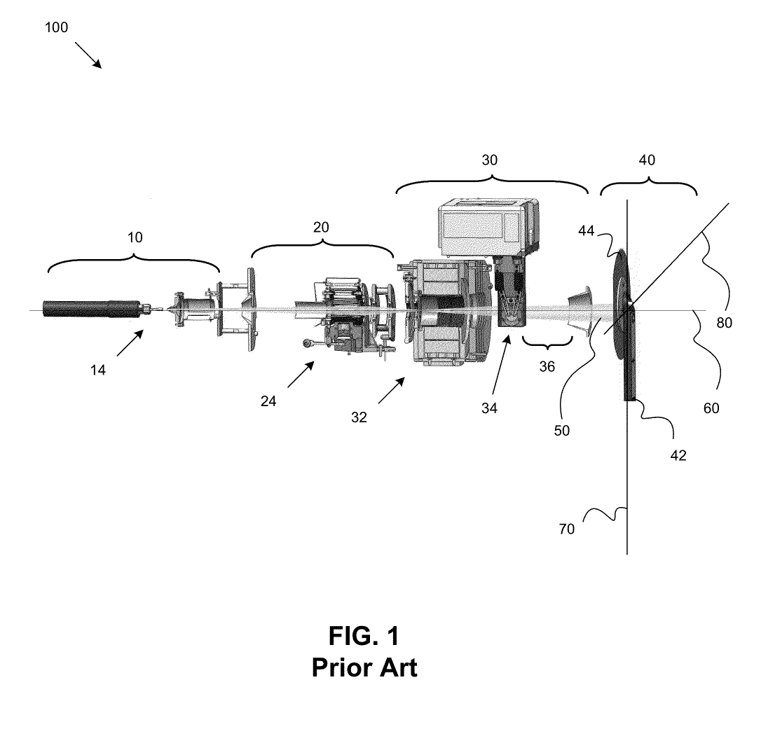

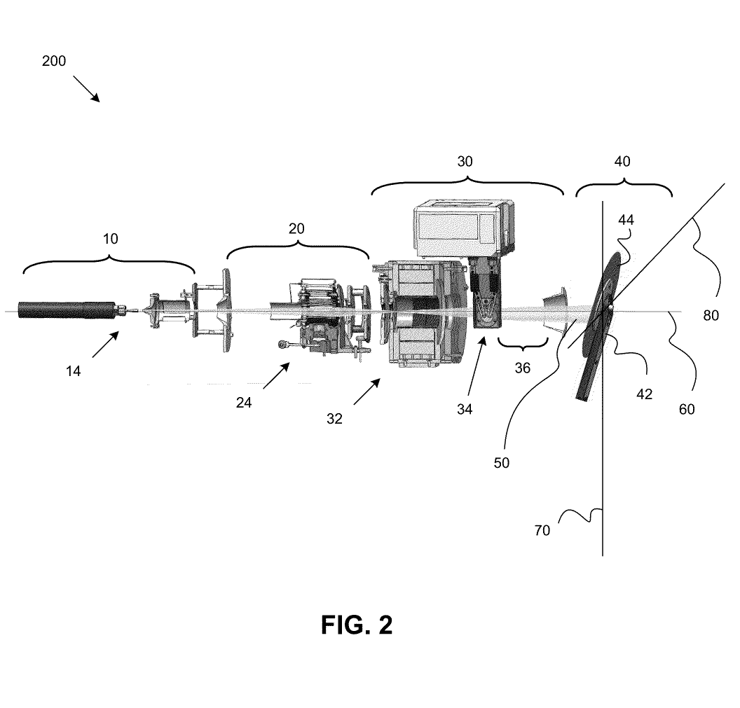

Referring now to FIG. 2, an angled GCIB system 200 according to an embodiment of the disclosed invention comprises some of the components described above regarding FIG. 1, wherein like elements have the same reference numerals. However, as shown in FIG. 2, the platen 42 is positioned such that the substrate 44 intercepts the beam 50 at an angle. The platen 42 and thereby the substrate 44 is positioned at an acute angle from at least one of a vertical axis 70 or the horizontal axes 60 and 80. The vertical axis 70 and the horizontal axis 80 are substantially perpendicular from a second horizontal axis 60 along the length of the GCIB modules 10, 20, 30, and 40. In related embodiments, the platen 42 or the substrate 44 may be fixed at an angular position relative to the beam 50, or their angle may be adjustable along the axes 60, 70 or 80 using a pivotable member, connected to the platen 42 to adjust the substrate 44 (as shown, for example, in FIG. 2,). For example, a ball joint connected to the platen may enable “X”, “Y” and “Z” adjustments, that is, along the axes 60, 70 and 80. The platen 42 and the substrate 44 are movable along each of the axes 70 and 80.

According to a further embodiment of the disclosed invention, the platen 42 and/or the substrate 44 are additionally configured to move along the axis 60, towards or away from the beam 50 source (i.e., the third module 30), such that the center of the beam 50 collides with the surface of the substrate 44 at a configurable distance, preferably at a substantially equal distance for each portion of the substrate 44 that is scanned by the beam 50. Angularly positioning, i.e., tilting, the platen 42 and the substrate 44 results in one portion of the substrate 44 being closer to the beam 50 than an opposing end. With the beam 50 source being stationary, moving the platen 42 along the axes 70 or 80 (depending on the direction of the tilt) during the GCIB scan process results in an increased distance between an emission point of the beam 50 from the third module 30 and the surface of the substrate 44 as the length of the substrate 44 is scanned. By allowing the platen 42 to move along the axis 60, therefore, the distance between the emission point of the beam 50 from the third module 30 and the surface of the substrate 44, is configurable, and can be maintained at a substantially constant value. For example, as the beam 50 is projected onto successively farther portions of the substrate 44, the platen 42 may be stepped forward, i.e. moved closer to the beam 50 source, to cancel out the added distance between the two. The reference point for this distance may be, for example, the center of the beam 50 at the point where it collides with the substrate 44.

In a related embodiment, the emission point 36 of the third module 30 is mechanically movable along the axis 60, such that it allows adjustment of the distance travelled by the beam 50 before it is intercepted by the substrate 44. This feature allows the angled GCIB device to maintain an equal distance between the emission point 36 of the beam 50 and the point of contact on the substrate 44 (measured, for example, at the center of the beam at the point of contact), or to vary the distance in a controlled way.

A given portions(s) of the substrate 44 may be scanned multiple times with varying intensity to achieve a desired level of surface manipulation, such as substantially uniform manipulation. Additionally, the speed at which the platen 42 is moved may be changed to further facilitate this objective.

Using the angled GCIB system 200, it is possible to treat the surface of the substrate 44 asymmetrically by adjusting the angle at which the substrate 44 intercepts the beam 50. By tilting the substrate 44, the ionized gas clusters in the beam 50 collide with surface features of the substrate 44 from an exposed side, leaving surface features of the other side virtually unexposed. GCIB deposition, etching, implantation, and related processes, therefore, may be performed asymmetrically, as claimed, and as illustrated by embodiments described below.

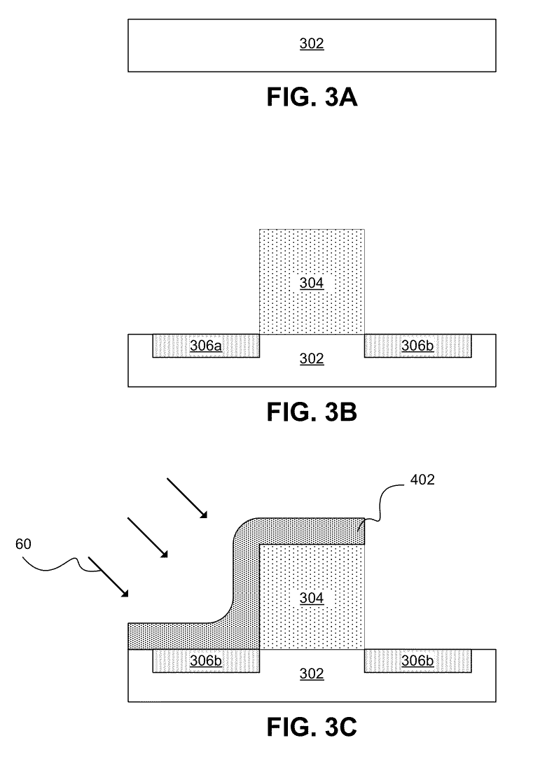

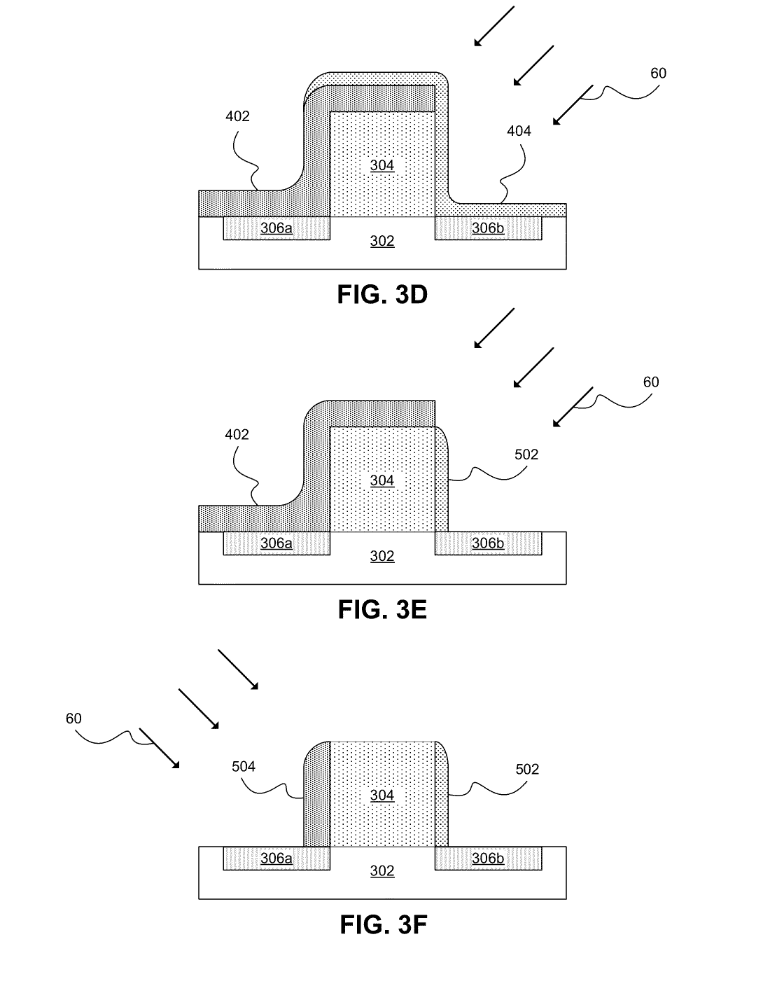

Referring now generally to FIGS. 3A-F, an exemplary embodiment of the disclosed invention is shown and discussed hereinafter. FIG. 3A depicts a base substrate layer 302 according to any known method in the art. Although only one substrate layer is shown, embodiments of the disclosed invention may comprise multi-layered substrates, including a buried oxide (BOX) layer (not shown), or a semiconductor-on-insulator (SOI) layer (not shown). The base substrate layer 302 may be made of any semiconductor material including, without limitation: silicon, germanium, silicon-germanium alloy, silicon carbide, silicon-germanium carbide alloy, and compound (e.g. III-V and II-VI) semiconductor materials. Non-limiting examples of compound semiconductor materials include gallium arsenide, indium arsenide, and indium phosphide. A BOX layer (not shown) may be formed from any of several dielectric materials. Non-limiting examples include: oxides, nitrides, and oxynitrides of silicon, and combinations thereof. Oxides, nitrides, and oxynitrides of other elements are also envisioned. Further, the BOX layer (not shown) may include crystalline or non-crystalline dielectric material. The BOX layer (not shown) may be approximately 5 to approximately 500 nm thick, preferably approximately 200 nm. A SOI layer (not shown) may be made of any of the several semiconductor materials possible for base substrate layer 302. In general, the base substrate layer 302 and the SOI layer (not shown) may include either identical or different semiconducting materials with respect to chemical composition, dopant concentration and crystallographic orientation. The SOI layer (not shown) may be p-doped or n-doped with a dopant concentration of approximately 1×10¹⁵ to approximately 1×10¹⁸/cm³, preferably approximately 1×10¹⁵/cm³. The SOI layer (not shown) may be approximately 2 to approximately 300 nm thick, preferably approximately 5 to approximately 100 nm.

Referring now to FIG. 3B, a gate 304 is formed over a central portion of the base substrate layer 302. The gate 304 may include a gate electrode, a gate dielectric, and a gate hard mask (not shown), made of, for example, a nitride material, and may be approximately 20 nm to approximately 150 nm thick, preferably approximately 50 nm. In some embodiments, the gate 102 may be formed using a gate-first process, in which case the gate electrode may further include a set of work-function metal layers, and a metal fill layer. The gate dielectric layer may be made of metal oxides, metal silicates, metal nitrides, transition metal oxides, transition metal silicates, transition metal nitrides, or combinations thereof, and may be approximately 1 nm to approximately 5 nm thick. Exemplary gate dielectric layer materials include silicon dioxide, hafnium oxide, and aluminum oxide. The work-function metal layers may include multiple metal-containing layers and may be made of titanium nitride, tantalum nitride, or titanium-aluminum and may be approximately 20 to approximately 100 angstroms thick. The metal fill layer may be made of, for example, silicon, aluminum, copper, tungsten, or some combination thereof. Other embodiments may include more or less metal layers depending on the application and the types of devices being formed. The composition of each metal layer may also vary and the process of selecting the material for each metal layer is known in the art.

In other embodiments, the gate 304 may be formed using a gate-last process, in which case the gate 304 may include a dummy gate layer made of, for example, silicon, and a dummy gate dielectric made of, for example, silicon oxide, intended to serve as a placeholder for the replacement gate formed after later processing steps. The gate 304 is replaced with a true gate dielectric and a gate conductor during subsequent processes.

Further referring to FIG. 3B, a source region 306a and a drain region 306b is formed on opposing sides of the gate 304 onto the substrate layer 302, using any known method in the art, including, for example, lithography and ion implantation. It is not essential to the practice of the disclosed invention to form the source/drain regions 306a and 306b, although this step is typically included in existing fabrication processes. Moreover, it is not necessary for these regions to be formed before sidewall spacers. Each of these two regions is referred to as either a source or a drain for ease of reference. However, embodiments of the disclosed invention may have the source region formed on the area denoted by 306b, and the drain region formed in the area denoted by 306a.

Referring now to FIG. 3C, using an angled GCIB system, a spacer film layer 402 is selectively deposited onto a top and a first side of the semiconductor structure comprising the substrate layer 302 and the gate 304 formed thereon, such that the spacer film layer 402 is not formed onto a second side of the gate 304 opposite the first side. Such selective deposition is achieved by tilting the platen 42 (or the substrate 44) at a 45° angle relative to the direction of the beam 50, such that the ionized gas clusters collide with only the first side of the gate 304. Since there is no direct path between the ionized gas clusters and the second side of the gate 304, the second side is left virtually unaffected by the angled deposition.

In a related embodiment, the spacer film layer 402 may be formed on the top side, the first side and the second opposite side of the gate structure 304 using angled GCIB deposition, and thereafter selectively removed by any known means (including angled GCIB etching) so that the spacer film layer 402 is removed almost entirely from the second side of the gate 304, or is removed partially so that the spacer film layer 402 is thicker on the first side of the gate 304 than it is on the second side.

Referring now to FIG. 3D, a second spacer film layer 404 is formed on the top side and the second side of the gate 304 comprising the substrate layer 302, the gate 304, and the deposited spacer film layer 402, such that the spacer film layer 404 is not formed on the first side of the gate 304. In a related embodiment, the spacer film layer 404 may be formed on the first side, the second side, and the top side of the gate 304, and thereafter selectively removed by any known means, (such as angled GCIB etching) so that the spacer film layer 404 is removed from at least the first side of the gate 304.

Although the spacer film layer 402 forms a thicker layer than the spacer film layer 404 in the depicted embodiment, the spacer film layer 402 may in fact be the thinner layer of the two in other embodiments. In other words, it is not necessary that the thicker layer of the two spacer films be deposited first.

Referring now to FIG. 3E, the spacer film layer 404 is selectively removed by applying an angled GCIB etch to form a first spacer 502 on the second side of the gate 304. Because the spacer film layer 402 is different from the spacer film layer 404, the two materials react differently, or not at all, with a given type of ionized gas cluster. Therefore, by utilizing a gas whose ionized clusters react only with the spacer film layer 404, it is possible to form the spacer 502 at a desired thickness and shape without affecting the thickness or shape of the spacer film layer 402. Moreover, even if the same gas is used, the angularity of the beam 50 ensures that there is no substantial effect on the spacer 502.

Referring now to FIG. 3F, the spacer film layer 402 is also removed by angled GCIB etch in the same manner as described above, to form a second spacer 504 on the first side of the gate 304.

The resulting structure shown in FIG. 3F comprises the substrate layer 302, the gate layer 304, and the spacers 502 and 504. According to the disclosed embodiment, the spacers 502 and 504 are formed using different materials, and have different thicknesses. Consequently, each spacer possesses a different dielectric capacitance that is, in part, a function of its material (having a distinct dielectric constant) and thickness. The spacer 504 is formed using an oxide compound and is thicker than the spacer 502, which is formed using a nitride compound. Preferably, the oxide spacer 504 has a thickness of 10 nm, and the nitride spacer 502 has a thickness of 5 nm. Generally, nitride compounds have a higher dielectric constant than oxide compounds. Additionally, since the dielectric capacitance of the resulting structures is inversely proportional to their thicknesses, the thicker oxide spacer 504 has a lower capacitance than the thinner nitride spacer 502. The oxide spacer 504 is formed on the drain side of the gate 304, and the nitride spacer 502 is formed on the source side of the gate 304.

In a related embodiment, the spacer 504 may be formed using an oxide compound (having, for example, a dielectric constant of 3.9 k), and the spacer 502 may be formed using a second compound having a lower dielectric constant, such as carbon doped-silicon oxide.

Although angled GCIB is applied to the substrate 44 during both the deposition and etching steps of the disclosed embodiments, other embodiments may employ angled GCIB for only the deposition or only the etching step without departing from the scope and spirit of the disclosed invention. Moreover, it is not necessary that angled GCIB deposition or etching be used in creating both of the spacers 502 and 504, or in forming or shaping both of the spacer film layers 402 and 404. For example, the spacer film layer 404 may be etched using angled GCIB to form the spacer 502, and the spacer 504 may be formed using any known etching technique in the art, such as reactive ion etching (RIE), without any angularity. In other words, using angled GCIB deposition/etching is not necessary in every deposition/etching step in order to create asymmetric structures.

Furthermore, although preferred embodiments of the disclosed invention comprise the application of a GCIB system (including both for deposition and etching steps) at a non-perpendicular angle relative to the substrate 44, such a system may nevertheless apply a beam 50 to the substrate 44 at a right angle. Among having other benefits, this feature of the disclosed invention preserves the functionality of existing GCIB systems without creating the need to process the substrate 44 in a different GCIB system for applications requiring such treatment.

Additionally, while the recited exemplary embodiments of the disclosed invention involve using an angled GCIB system for deposition and etching steps in the semiconductor fabrication processes, such uses are non-limiting. An angled GCIB system may be used for any other treatment of a surface, including a semiconductor wafer, where asymmetric application of a GCIB is required or useful.

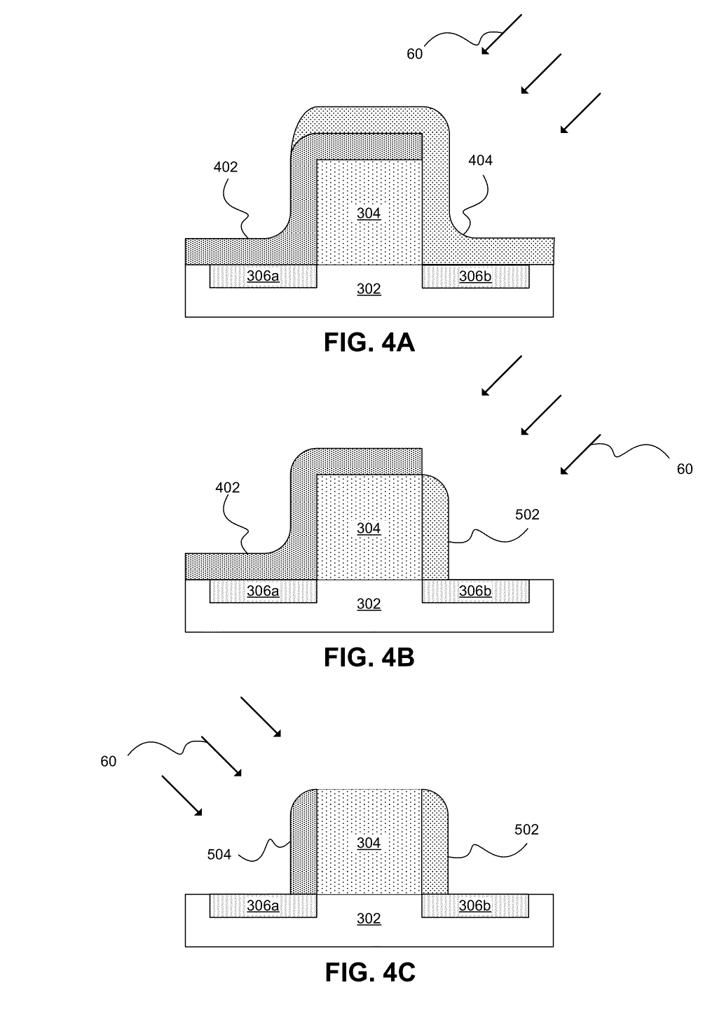

Referring now generally to FIGS. 4A-C, a further embodiment of the disclosed invention includes the steps of forming a substrate layer 302, a gate 304, a source region 306a, a drain region 306b, and a first spacer film layer 402, as in the same manner described above and depicted in FIGS. 3A-C (these steps are not duplicated in FIGS. 4A-C).

Referring now specifically to FIG. 4A, a second spacer film layer 404 is deposited onto the gate 304, the substrate layer 302, and the drain region 306b by angled GCIB deposition, using the gas cluster beam 50, to form a layer that is of substantially equal thickness relative to the spacer film layer 402. Alternatively, the spacer film layer 404 may be formed at a thickness that can be etched to form final spacer structures on each side of the gate 304 that are substantially equal in thickness.

Referring now to FIG. 4B, the spacer film layer 404 is modified using directional GCIB etching, or any known method in the art (such as RIE), to form a first spacer 502 on a first sidewall of the gate 304 and onto the substrate 302 and the drain region 306b.

Referring now to FIG. 4C, the spacer film layer 402 is modified using directional GCIB etching, or any known method in the art (such as RIE), to form a second spacer 504 on the a second sidewall of the gate 304, and onto the substrate 302 and the source region 306a.

The resulting structure depicted in FIG. 4C comprises the substrate layer 302 having the source region 306a, the drain region 306b, and the two spacers 502 and 504 made from different materials but having substantially equal thicknesses.

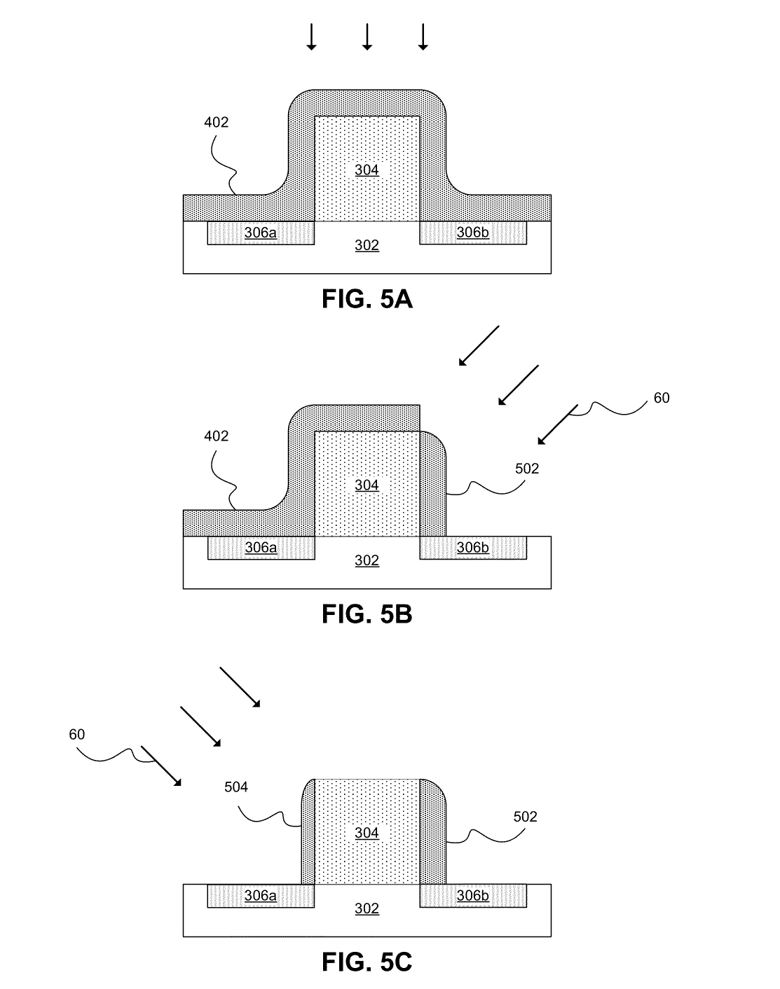

Referring now generally to FIGS. 5A-C, a further embodiment of the disclosed invention comprises the steps of forming a gate 104 on a substrate layer 102, the gate 304 flanked by a source region 306a and a drain region 306b, as described above and depicted in FIGS. 3A-C (these steps are not duplicated in FIGS. 5A-C).

Referring now specifically to FIG. 5A, a spacer film layer 402 is formed onto the top and sidewall surfaces of the gate 304 and the substrate layer 302, including over the source/drain regions 306a and 306b, using any known method in the art, including existing GCIB deposition or other deposition methods.

Referring now to FIG. 5B, the spacer film layer 402 is selectively etched on one side of the gate 304, where the drain region 306b is formed, using angled GCIB etching, to form a first spacer 502. Because only one side of the gate 304 structure and its immediate periphery is exposed to the beam 50, its other side does not react with the beam 50 and is therefore left virtually unchanged by the angled GCIB etch at this stage.

Referring now to FIG. 5C, the spacer film layer 402 is further etched on the other side of the gate 304, where the source region 306a is formed, using angled GCIB etching, to form a second spacer 504. As before, the spacer film layer 402 is affected only the exposed side of the gate 304. The first spacer 502 is virtually unaffected by the second angled GCIB etch. Consequently, by changing the specific makeup of the beam 50 and/or the length of time the substrate 44 is exposed to the beam 50, the second spacer 504 is formed with a lesser thickness than the first spacer 502. The resulting structure comprises the substrate layer 302, and the gate 304 flanked by the sidewall spacers 502 and 504 and the source/drain regions 306a and 306b.

In related embodiments, the angled GCIB system may be used to perform only a part of the deposition or etching processes described above, without departing from the scope or spirit of the disclosed invention. For example, a process may aim to form a first and a second nitride spacer having final thicknesses of 10 nm and 5 nm respectively, the first and second spacers being formed adjacent to a gate electrode. The process may include depositing a uniform nitride layer having a thickness of 20 nm on a semiconductor wafer having a plurality of gate electrodes on its surface. Forming the first and second spacers, then, requires removing approximately 10 nm and 15 nm of the 20 nm nitride layer, from respective sides of the plurality of gate electrodes. Since forming both spacers requires removing at least a 10 nm top layer of nitride, a conventional etching process may be used to remove the top layer with substantial uniformity; the two spacers may be formed, at this stage, at a thickness of 10 nm. In other words, it is not necessary to use angled GCIB etch to perform this step. It may be desirable to use a conventional etching process due, for example, to time and cost constraints.

Subsequently, angled GCIB etch may be used to etch the second spacer in order to etch an additional 5 nm layer, without etching the first spacer. The resulting structure comprises the first spacer having a thickness of 10 nm, and the second spacer having a thickness of 5 nm.

Similarly, in deposition steps, it may not be necessary to use angled GCIB to deposit all the material needed to form a first and a second spacer film layer on respective sides of a gate electrode. For example, if the first spacer film layer is to be formed at 10 nm, and the second spacer film layer is to be formed at 5 nm, it is possible to use a conventional deposition technique to form a base layer of 5 nm on both sides of the gate electrode. Thereafter, an additional layer having a thickness of 5 nm may be formed only on the side of the first spacer film layer to achieve the desired 10 nm thickness.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable other of ordinary skill in the art to understand the embodiments disclosed herein. It is therefore intended that the present invention not be limited to the exact forms and details described and illustrated but fall within the scope of the appended claims.

We claim:

1. An angled gas cluster ion beam system, comprising:
a first module for forming a collection of gas clusters;
a second module for generating a gas cluster beam by using the collection of gas clusters formed by the first module, the second module communicating with the first module along a first axis extending through the modules;
a third module for ionizing the gas cluster beam generated by the second module and for directing the gas cluster beam along the first axis, the third module communicating with the second module along the first axis; and
a fourth module for housing a target surface, the fourth module configured to position the target surface at an acute angle from at least a second axis being substantially perpendicular to the first axis to intercept the gas cluster beam directed by the third module, the fourth module communicating with the third module along the first axis.

2. The system of claim 1, wherein the first axis is substantially horizontal extending longitudinally along a substantially central length of the first, second, and third modules, and the second axis is substantially vertical and perpendicular to the first axis.

3. The system of claim 1, wherein the target surface is rotatable about the first and second axes, and rotatable about a third axis being substantially perpendicular to both the first and the second axes.

4. The system of claim 1, wherein the target surface is movable along the first and second axes, and along a third axis being substantially perpendicular to both the first and the second axes.

5. The system of claim 1, wherein the third module further comprises a beam emission point movable along the first axis.

6. The system of claim 1, wherein the target surface is a semiconductor wafer.

7. The system of claim 1, wherein the target surface is a fixed disk memory system.

8. The system of claim 1, wherein the acute angle is approximately between 1 and 30 degrees.

9. The system of claim 1, wherein the acute angle is adjustable.

10. The system of claim 9, wherein the acute angle is further adjustable to form a perpendicular angle.

11. A method for forming asymmetric structures using a angled gas cluster ion beam system, comprising:
forming a collection of gas clusters, using a first module;
generating a gas cluster beam from the collection of gas clusters, using a second module;
ionizing the gas cluster beam and directing the gas cluster beam along a first axis, using a third module; and
intercepting the ionized gas cluster beam, using a fourth module, by positioning a target surface at an acute angle from a second axis being substantially perpendicular to the first axis.

12. The method of claim 11, further comprising rotating the target surface about the first and the second axes, and about a third axis being substantially perpendicular to both the first and the second axes.

13. The method of claim 11, further comprising moving the target surface along the first and second axes, and along a third axis being substantially perpendicular to both the first and second axes.

14. The method of claim 11, wherein the ionized gas cluster beam deposits material onto the target surface.

15. The method of claim 11, wherein the ionized gas cluster ion beam implants material into the target surface.

16. The method of claim 11 wherein the gas cluster ion beam etches material from the target surface.

17. The method of claim 14 wherein the target surface is a semiconductor wafer and the angled gas cluster ion beam deposits a spacer film layer onto a gate electrode on a surface of the semiconductor wafer.

18. The method of claim 16 wherein the target surface is a semiconductor wafer and the angled gas cluster ion beam etches a spacer film layer formed onto a surface of a gate electrode on a surface of the semiconductor wafer.

19. A method for forming asymmetric structures on a target surface, comprising:
generating a gas cluster ion beam;
directing the gas cluster ion beam along a first axis;
intercepting the gas cluster ion beam using a target surface, wherein the target surface is positioned at an acute angle from a second axis being substantially perpendicular to the first axis.

20. The method of claim 19, wherein the target surface is rotatable about the first and second axes, and rotatable about a third axis being substantially perpendicular to both the first and the second axes.

21. The method of claim 19, wherein the target surface is movable along both the first and second axes, and along a third axis being substantially perpendicular to the first and second axes.

22. The method of claim 19, wherein the target surface is a semiconductor wafer.

23. The method of claim 19, wherein the acute angle is between 1 and 30 degrees.

24. The method of claim 19, wherein the acute angle is adjustable.

25. The method of claim 19, wherein the acute angle is further adjustable to form a perpendicular angle.
